(19) United States
(12) Patent Application Publication
(10) Pub. No.: US 2025/0251433 A1
(43) Pub. Date: Aug. 7, 2025

(54) HARMONIC INFORMATION EXTRACTION CIRCUIT

(71) Applicant: Delta Electronics (Shanghai) Co., Ltd., Shanghai (CN)

(72) Inventors: Ting Li, Shanghai (CN); Kai Dong, Shanghai (CN); Dongyu Wang, Shanghai (CN); Chang Xu, Shanghai (CN); Yichao Wang, Shanghai (CN); Hui Wang, Shanghai (CN); Siyu Chen, Shanghai (CN)

(21) Appl. No.: 19/015,613

(22) Filed: Jan. 9, 2025

(30) Foreign Application Priority Data
Feb. 2, 2024 (CN) 202410154353.0

(51) Int. Cl. G01R 23/165

(52) U.S. Cl. CPC G01R 23/165

(57) ABSTRACT

A harmonic information extraction circuit is provided. The harmonic information extraction circuit includes a sampling module, an amplitude regulation module and an envelope extraction module. The sampling module is electrically connected to signal terminals of an electronic equipment to acquire a first sampling signal, and generates a first output signal. The first sampling signal includes first and second target band signals and a non-target band signal. The amplitude regulation module receives the first output signal, adjust at least one of an amplitude of the first target band signal and an amplitude of the second target band signal for ensuring that a ratio of the amplitude of the first target band signal to the amplitude of the second target band signal falls within a preset range, and generates a second output signal. The envelope extraction module receives the second output signal and extracts an envelope of the second output signal.

### CROSS-REFERENCE TO RELATED APPLICATION

This application claims priority to China Patent Application No. 202410154353.0, filed on Feb. 2, 2024, the entire contents of which are incorporated herein by reference for all purposes.

### FIELD OF THE INVENTION

The present disclosure relates to a harmonic information extraction circuit, and more particularly to a harmonic information extraction circuit capable of extracting harmonic information of target frequency bands from an electronic equipment.

### BACKGROUND OF THE INVENTION

In recent years, with the rapid development of machine learning and artificial intelligence, prognostics health management (PHM) technology has gradually become an emerging trend in the field of equipment operation and maintenance. Through extracting relevant health information, the PHM technology can estimate the current performance status of equipment in real-time so as to provide timely warnings of potential failures and prevent serious breakdowns. Additionally, the PHM technology can accurately predict the remaining lifespan of equipment according to historical information. Thereby, the operation and maintenance strategies can be rationally scheduled to extend the equipment usage and save maintenance costs.

The key to PHM technology lies in extracting health information of equipment. Typically, when the components of an equipment undergo performance degradation, detectable shifts occur in the time or frequency domain characteristics of relevant signals (e.g., voltage signals, current signals and vibration signals) during operation. The health status of the equipment can be reflected by measuring the shifts of relevant characteristics. However, it is really a challenge to extract health information during actual operation.

Firstly, the signal characteristic shifts caused by equipment or component aging are usually extremely small compared to regular operating signals. Taking a DC-link capacitor as an example, its rated operating voltage is generally several hundred to several thousand volts, while the increase in harmonic amplitude due to capacitance decrement is usually only a few volts or tens of millivolts. This means that the extremely small changes caused by equipment or component aging would be hidden within the high-amplitude operating signals. Therefore, the sampling system needs to be capable of shielding the influence of high-amplitude signals and ensuring sufficient sampling accuracy for low-amplitude signals at the same time. In many cases, sampling systems struggle to meet these requirements, necessitating system downtime and additional equipment for measurement, which limits the practical application of PHM technology.

Secondly, the conventional health information extraction circuit only extract signals from a single frequency band, and the monitored target components are limited to a single type with a deficient number. Actually, the increase in harmonic amplitude caused by the aging of different components would be unevenly distributed across different frequency bands. Since one conventional extraction circuit can only monitor a few components corresponding to one single frequency band, the unit investment cost required for the PHM technology increases. Considering cost, the effect achieved by the PHM strategy with low coverage is also limited, ultimately resulting in an imbalance between investment cost and expected benefit, which reduces the attractiveness of PHM technology.

Therefore, there is a need of providing a harmonic information extraction circuit in order to overcome the drawbacks of the conventional technologies.

### SUMMARY OF THE INVENTION

The present disclosure provides a harmonic information extraction circuit capable of extracting harmonic signals of one or more target frequency bands from regular operating signals of an electronic equipment when multiple harmonic sources exist in the electronic equipment.

In accordance with an aspect of the present disclosure, a harmonic information extraction circuit is provided. The harmonic information extraction circuit includes a sampling module, an amplitude regulation module and an envelope extraction module. The sampling module is electrically connected to a first signal terminal and a second signal terminal of an electronic equipment, and is configured to acquire a first sampling signal of the electronic equipment and generate a first output signal. The first sampling signal includes a first target band signal, a second target band signal and a non-target band signal. The amplitude regulation module is electrically connected to the sampling module to receive the first output signal and is configured to adjust at least one of an amplitude of the first target band signal and an amplitude of the second target band signal for ensuring that a ratio of the amplitude of the first target band signal to the amplitude of the second target band signal falls within a preset range, and the amplitude regulation module generates a second output signal. The envelope extraction module is electrically connected to the amplitude regulation module to receive the second output signal, and extracts an envelope of the second output signal.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic block diagram illustrating an electronic equipment and a harmonic information extraction circuit according to an embodiment of the present disclosure;

FIG. 2 schematically shows the amplitude variation process of the sampling signal processed by the harmonic information extraction circuit;

FIG. 3A, FIG. 3B, FIG. 3C and FIG. 3D exemplify several possible implementations of the harmonic information extraction circuit;

FIG. 4 exemplifies a specific circuit topology of the harmonic information extraction circuit according to an embodiment of the present disclosure;

FIG. 5 exemplifies a specific circuit topology of the harmonic information extraction circuit according to another embodiment of the present disclosure; and

FIG. 6 exemplifies a specific circuit topology of the harmonic information extraction circuit according to further another embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

In the present disclosure, the terms like “include”, “comprise” and “have” are open-ended, namely these terms means including but not being limited to. In addition, the terms “connect” and “couple” both means that two or more elements are physically contacted or electrically connected, directly or indirectly.

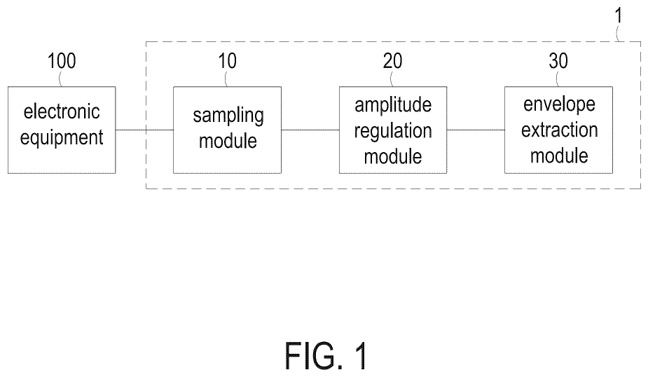

FIG. 1 is a schematic block diagram illustrating an electronic equipment and a harmonic information extraction circuit according to an embodiment of the present disclosure. As shown in FIG. 1, the harmonic information extraction circuit 1 includes a sampling module 10, an amplitude regulation module 20 and an envelope extraction module 30. The sampling module 10 is electrically connected to a first signal terminal and a second signal terminal of the electronic equipment 100, and is configured to acquire a first sampling signal of the electronic equipment 100 and generate a first output signal. The first sampling signal includes a first target band signal, a second target band signal and a non-target band signal, and the first and second target band signals are generated by different harmonic sources in the electronic equipment 100. When the components corresponding to different harmonic sources degrade or age, the harmonic characteristics (harmonic amplitude or frequency) of different target band signals may change. After passing through the sampling module 10, the non-target band signal of the first sampling signal is significantly suppressed, so the influence of the non-target band signal in the first output signal can be ignored.

The amplitude regulation module 20 is electrically connected to the sampling module 10 for receiving the first output signal. The amplitude regulation module 20 adjusts at least one of an amplitude of the first target band signal and an amplitude of the second target band signal for ensuring that a ratio of the amplitude of the first target band signal to the amplitude of the second target band signal falls within a preset range, and the amplitude regulation module 20 generates a second output signal. It should be noted that, according to actual requirements, the amplitude regulation module 20 may adjust the amplitudes of one or more target band signals in the first output signal to make the second output signal emphasize reflecting the information of the desired target band signal. For example, in an embodiment, the amplitude regulation module 20 simultaneously adjusts the amplitudes of both the first and second target band signals, which allows the second output signal to reflect the information of both the first and second target band signals. Further, the second output signal reflects the information of the first and second target band signals with the same weighting, and the second output signal can be used to determine the health status of the components associated with the two harmonic sources corresponding to the first and second target band signals. In another embodiment, the amplitude regulation module 20 may only adjust the amplitude of the second target band signal to significantly suppress it so that the second output signal only reflects the information of the first target band signal. Therefore, the health status of the components associated with the harmonic source corresponding to the first target band signal is targetedly determined according to the second output signal. Alternatively, the amplitude regulation module 20 may only adjust the amplitude of the first target band signal to significantly suppress it so that the second output signal only reflect the information of the second target band signal. Therefore, the health status of the components associated with the harmonic source corresponding to the second target band signal is targetedly determined according to the second output signal.

The envelope extraction module 30 is electrically connected to the amplitude regulation module 20 to receive the second output signal, and the envelope extraction module 30 extracts an envelope of the second output signal. The extracted envelope reflects the amplitude and frequency of the second output signal.

Consequently, when multiple harmonic sources exist in the electronic equipment 100, the harmonic information extraction circuit 1 is able to extract complete harmonic signals of one or more target frequency bands from regular operating signals. Based on the extracted harmonic signals, the health status (i.e., the performance status) of the electronic equipment 100 and the components thereof can be evaluated. For example, according to the amplitude and frequency characteristics included in the output signal, the health status of the electronic equipment 100 and the components thereof can be determined through data processing, machine learning, and artificial intelligence algorithms, etc.

In an embodiment, the sampling module 10 includes at least one filter unit configured to suppress the amplitude of the non-target band signal. Through the suppression of the filter unit, the influence of the non-target band signal in the first output signal can be ignored, while the attenuation of target band signals is small. In addition, depending on the magnitude relations between the frequency of the non-target band signal and the frequencies of the target band signals, the filter unit may include different kinds of filters to allow the target band signals to pass through and to suppress the non-target band signal in the meantime. As an example, when the frequency of the non-target band signal is lower than the frequencies of the target band signals, the filter unit may include a high-pass filter or a band-pass filter. Conversely, when the frequency of the non-target band signal is higher than the frequencies of the target band signals, the filter unit may include a low-pass filter or a band-pass filter. Additionally, in an embodiment, the filter unit ensures that the amplitude attenuation of both the first and second target band signals does not exceed a preset threshold, which is for example but not limited to 0.3, thereby preserving the harmonic information of the first and second target band signals as much as possible.

In an embodiment, the sampling module 10 includes a voltage divider unit. The voltage divider unit is configured to perform voltage dividing and current limiting on the first sampling signal such that the maximum amplitude of the first output signal does not exceed a rated operating range of the amplitude regulation module 20.

In an embodiment, the sampling module 10 includes a clamping unit. The clamping unit is configured to perform voltage clamping on the first sampling signal such that the maximum amplitude of the first output signal does not exceed the rated operating range of the amplitude regulation module 20.

In an embodiment, the amplitude regulation module 20 includes a band-pass filter which may include an active band-pass filter or a passive band-pass filter. The band-pass filter is configured to adjust at least one of the amplitude of the first target band signal and the amplitude of the second target band signal so that the ratio of the amplitude of the first target band signal to the amplitude of the second target band signal falls within the preset range. The preset range may be [0.01, 100], but not exclusively. Moreover, according to the information of the target band signals reflected by the envelope of the second output signal, the preset range may be further divided. For example, when the preset range is [0.2, 5], the envelope of the second output signal reflects the relevant information (frequency and amplitude) of both the first and second target band signals. When the preset range is [0.01, 0.2), the influence of the amplitude of the first target band signal on the envelope of the second output signal can be ignored, and namely the envelope of the second output signal only reflects the relevant information of the second target band signal. When the preset range is (5, 100], the influence of the amplitude of the second target band signal on the envelope of the second output signal can be ignored, and namely the envelope of the second output signal only reflects the relevant information of the first target band signal.

It is noted that, for ease of understanding, the first sampling signal and the first and second target band signals are taken as an example for explanation in the present disclosure. However, actually, the number of sampling signals received by the sampling module 10 and the number of target bands included in each sampling signal are not limited. In an embodiment, the amplitude regulation module 20 further receives a second sampling signal which includes a third target band signal reflecting the relevant information (frequency and amplitude) of another harmonic source in the electronic equipment 100. The amplitude regulation module 20 adjusts the amplitude of the third target band signal so that the ratio of the amplitude of the third target band signal to the amplitude of one of the target band signals of the first output signal (e.g., the first target band signal) falls within the preset range. Accordingly, the signal input to the amplitude regulation module 20 includes the relevant information of the first, second and third target band signals, and the second output signal including the information of certain target band signals may be obtained by controlling the amplitude-frequency characteristics of the amplitude regulation module 20. For example, by significantly suppressing the first target band signal, the influence of the first target band signal on the second output signal can be ignored, thereby allowing the second output signal to reflect the relevant information about amplitude and frequency of the second and third target band signals. In addition, under the circumstance that the amplitude regulation module 20 receives the second sampling signal, the band-pass filter of the amplitude regulation module 20 may be further used to suppress at least one of the DC component and the high-frequency noise of the second sampling signal.

The second sampling signal may be sampled from any position in the electronic equipment 100. In an embodiment, the amplitude regulation module 20 further includes a signal amplification circuit. The signal amplification circuit is electrically connected between the band-pass filter of the amplitude regulation module 20 and the envelope extraction module 30, and is configured to provide the second sampling signal. In addition, in the case that the second sampling signal includes a DC component, the amplitude regulation module 20 may further include a high-pass filter. The high-pass filter is electrically connected between the band-pass filter of the amplitude regulation module 20 and the envelope extraction module 30, and is configured to suppress the DC component of the second sampling signal.

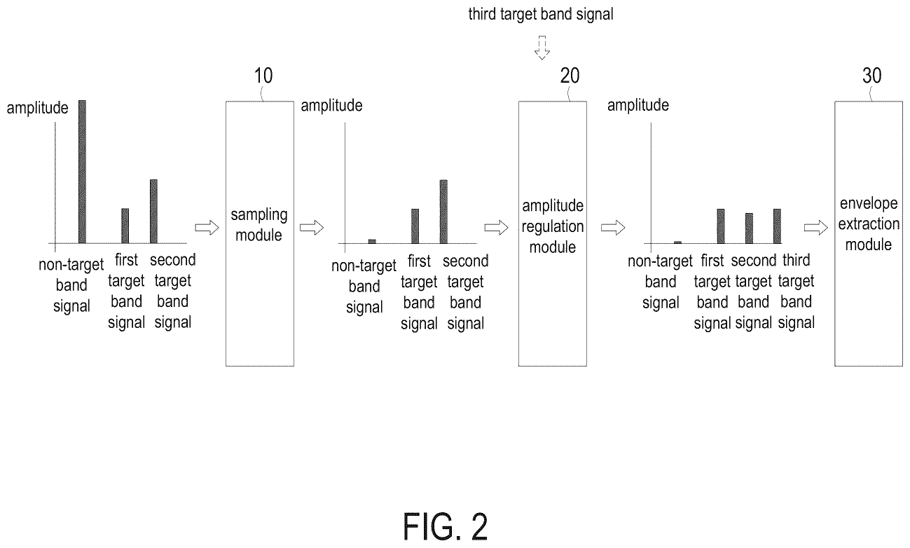

FIG. 2 schematically shows the amplitude variation process of the sampling signal processed by the harmonic information extraction circuit 1. As shown in FIG. 2, in this example, the sampling module 10 suppresses the amplitude of the non-target band signal of the first sampling signal, and the amplitude regulation module 20 receives the third target band signal. The amplitude regulation module 20 adjusts the amplitudes of the first, second and third target band signals to similar level and generates the second output signal accordingly so that the envelope extracted from the second output signal reflects the relevant information of the first, second and third target band signals.

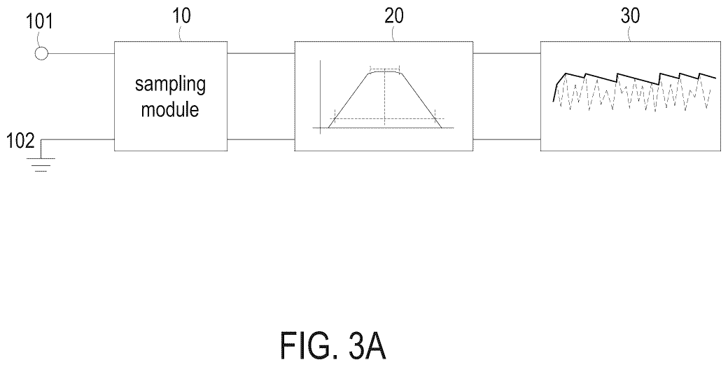

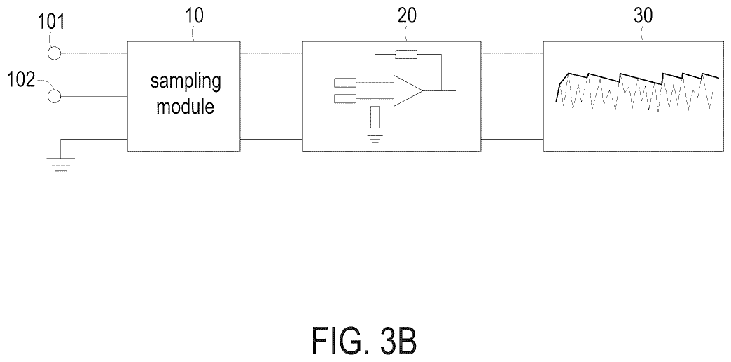

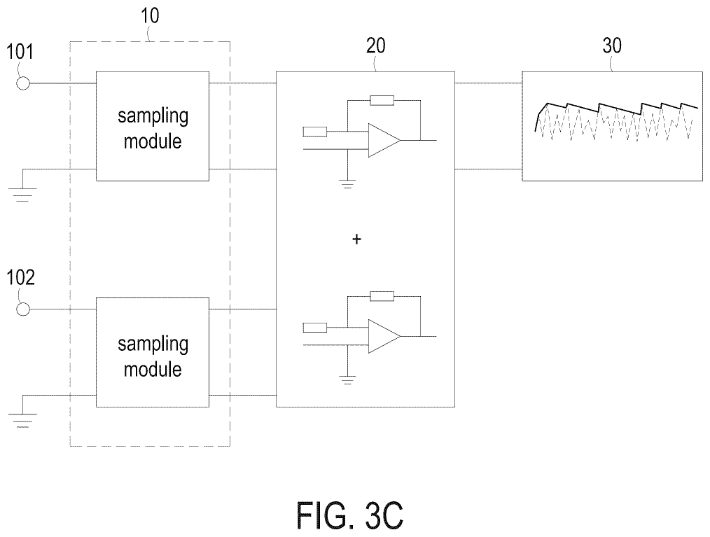

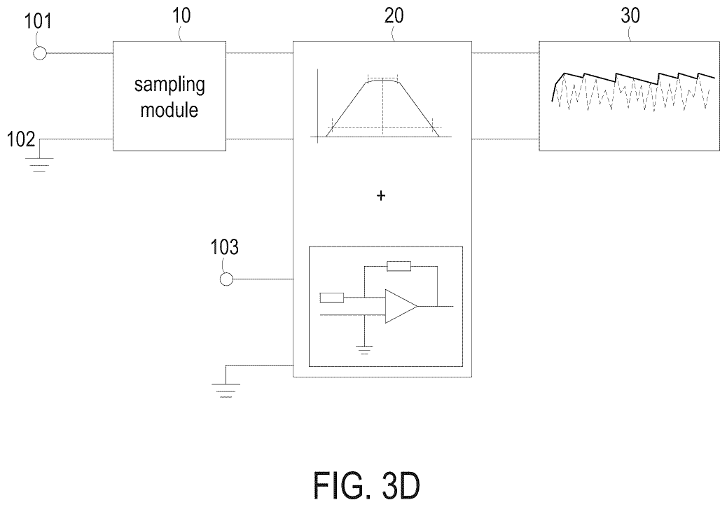

The specific implementation of the harmonic information extraction circuit 1 may be varied according to the number of first sampling signals and the type of band signals. FIGS. 3A, 3B, 3C and 3D exemplifies several possible implementations of the harmonic information extraction circuit 1, but it should be noted that the present disclosure is not limited thereto.

In the first implementation, the first sampling signal includes a plurality of target band signals. As exemplified in FIG. 3A, the sampling module 10 is electrically connected to the first signal terminal 101 and the second signal terminal 102 of the electronic equipment 100 to receive the first sampling signal including the first and second target band signals, and the second signal terminal 102 is a ground terminal. Under this circumstance, the amplitude regulation module 20 may utilize the amplitude-frequency characteristics of the filter circuit to adjust the amplitudes of different target band signals.

In the second implementation, the first sampling signal includes a plurality of target band signals including differential-mode and common-mode components. As exemplified in FIG. 3B, the sampling module 10 is electrically connected to the first signal terminal 101 and the second signal terminal 102 and the ground terminal of the electronic equipment 100 to receive the first sampling signal. The first signal terminal 101 and the second signal terminal 102 provide the first target band signal, which is a differential-mode component, of the first sampling signal. The second signal terminal 102 and the ground terminal provide the second target band signal, which is a common-mode component, of the first sampling signal. Under this circumstance, the amplitude regulation module 20 may utilize the common-mode suppression characteristics of the differential operational amplifier circuit to adjust the amplitudes of different target band signals.

In the third implementation, a plurality of first sampling signals includes a plurality of target band signals respectively. As exemplified in FIG. 3C, a part of the sampling module 10 is electrically connected to the first signal terminal 101 and the ground terminal of the electronic equipment 100 to receive the first target band signal of the first sampling signal, and another part of the sampling module 10 is electrically connected to the second signal terminal 102 and the ground terminal of the electronic equipment 100 to receive the second target band signal of the first sampling signal. Under this circumstance, the amplitude regulation module 20 may utilize the operational amplifier circuits with different gains to adjust the amplitudes of the different target band signals in different sampling signals.

In the fourth implementation, the first sampling signal includes a plurality of target band signals, and the amplitude regulation module 20 of the harmonic information extraction circuit 1 further receives a second sampling signal. As exemplified in FIG. 3D, the sampling module 10 is electrically connected to the first signal terminal 101 and the second signal terminal 102 of the electronic equipment 100 to receive the first sampling signal including the first and second target band signals, and the second signal terminal 102 is the ground terminal. The amplitude regulation module 20 is electrically connected to the third signal terminal 103 and the ground terminal of the electronic equipment 100 to receive the second sampling signal including the third target band signal. Under this circumstance, the amplitude regulation module 20 may utilize various ways to adjust the amplitudes of the first, second and third target band signals. For example, in this implementation, the amplitude regulation module 20 may utilize the amplitude-frequency characteristics of the filter circuits to adjust the amplitudes of the first and second target band signals and to simultaneously adjust the amplitude of the third target band signal. Based on the adjusted first, second and third target band signals, the second output signal is generated.

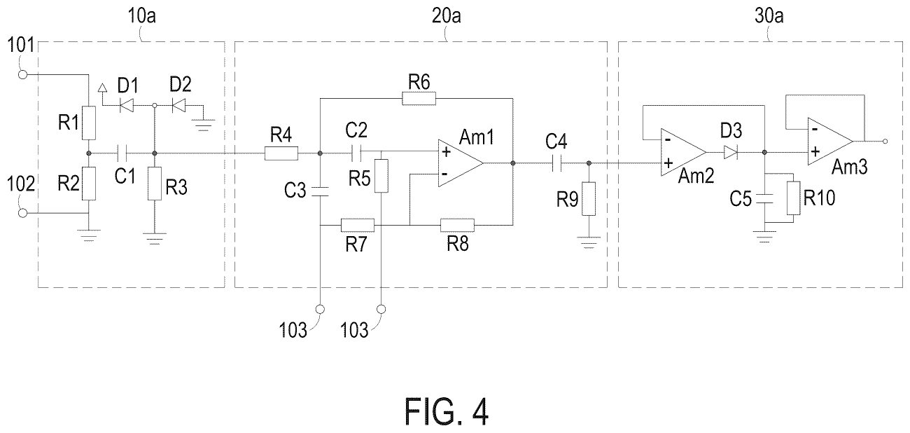

FIG. 4 exemplifies a specific circuit topology of the harmonic information extraction circuit according to an embodiment of the present disclosure. In this embodiment, the sampling module 10a includes a filter unit, a voltage divider unit and a clamping unit. The voltage divider unit includes resistors R1 and R2. A first terminal of the resistor R1 is electrically connected to the first signal terminal 101, a second terminal of the resistor R1 is electrically connected to a first terminal of the resistor R2, and a second terminal of the resistor R2 is electrically connected to the second signal terminal 102 and the ground terminal. The resistor R1 may have a large resistance value to limit the current. The filter unit includes a capacitor C1 and a resistor R3. Two terminals of the capacitor C1 are electrically connected to the second terminal of the resistor R1 and a first terminal of the resistor R3 respectively, and a second terminal of the resistor R3 is grounded. The clamping unit includes diodes D1 and D2 electrically connected in series. A cathode of the diode D1 is electrically connected to a DC power source to ensure that the input voltage of the amplitude regulation module 20a does not exceed the rated operating range of an operational amplifier Am1, an anode of the diode D1 is electrically connected to a cathode of the diode D2 and the first terminal of the resistor R3, and an anode of the diode D2 is grounded.

The amplitude regulation module 20a includes a band-pass filter and a high-pass filter. The band-pass filter includes the operational amplifier Am1, resistors R4, R5, R6, R7 and R8, and capacitors C2 and C3. A first terminal of the resistor R4 is electrically connected to the sampling module 10a, and two terminals of the capacitor C2 are electrically connected to a second terminal of the resistor R4 and a non-inverting input terminal of the operational amplifier Am1 respectively. Two terminals of the resistor R5 are electrically connected to the non-inverting input terminal of the operational amplifier Am1 and the third signal terminal 103 (providing the second sampling signal) respectively, and the third signal terminal 103 is a DC power source. Two terminals of the resistor R6 are electrically connected to the second terminal of the resistor R4 and an output terminal of the operational amplifier Am1 respectively. A first terminal of the capacitor C3 is electrically connected to the second terminal of the resistor R4, and a second terminal of the capacitor C3 is electrically connected to the third signal terminal 103 and a first terminal of the resistor R7. A second terminal of the resistor R7 is electrically connected to an inverting input terminal of the operational amplifier Am1 and a first terminal of the resistor R8, and a second terminal of the resistor R8 is electrically connected to the output terminal of the operational amplifier Am1. The band-pass filter has different gains for different frequencies, thus allowing different amplitude adjustments for the signals in different frequency bands. The high-pass filter includes a capacitor C4 and a resistor R9. Two terminals of the capacitor C4 are electrically connected to the output terminal of the operational amplifier Am1 and a first terminal of the resistor R9, and a second terminal of the resistor R9 is grounded. The high-pass filter may be used to suppress the DC component in the signal received from the third signal terminal 103.

The envelope extraction module 30a includes a diode D3, a resistor R10 and a capacitor C5. An anode of the diode D3 is electrically connected to the amplitude regulation module 20a, two terminals of the resistor R10 are electrically connected to a cathode of the diode D3 and the ground terminal respectively, and the capacitor C5 is electrically connected in parallel to the two terminals of the resistor R10. In an embodiment, the envelope extraction module 30a further includes a voltage follower formed by an operational amplifier Am2. A non-inverting input terminal of the operational amplifier Am2 is electrically connected to the amplitude regulation module 20a, an output terminal of the operational amplifier Am2 is electrically connected to the anode of the diode D3, and an inverting input terminal of the operational amplifier Am2 is electrically connected to the cathode of the diode D3. The diode D3 has a conduction voltage drop for about 0.7V, and the added voltage follower may be used to compensate the conduction voltage drop of diode. In an embodiment, the envelope extraction module 30a further includes an operational amplifier Am3 having a non-inverting input terminal electrically connected to the cathode of the diode D3. The operational amplifier Am3 also operate as a voltage follower to increase the output signal gain and simultaneously increase the output impedance of circuit, thereby preventing the charging and discharging network formed by the resistor R10 and the capacitor C5 from being affected by post-stage circuits.

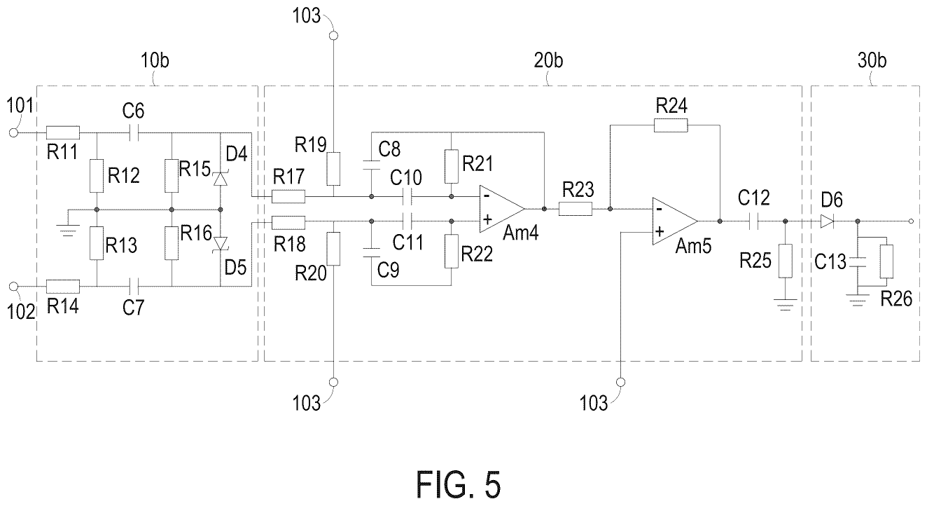

FIG. 5 exemplifies a specific circuit topology of the harmonic information extraction circuit according to another embodiment of the present disclosure. In this embodiment, regarding the first sampling signal provided by the first signal terminal 101 and the second signal terminal 102, the first target band signal is a differential-mode signal, and the second target band signal is a common-mode signal. As shown in FIG. 5, the sampling module 10b includes a first filter unit, a second filter unit, a first voltage divider unit, a second voltage divider unit, a first clamping unit, and a second clamping unit. The first voltage divider unit is electrically connected to the first signal terminal 101 and the ground terminal and includes resistors R11 and R12. The second voltage divider unit is electrically connected to the second signal terminal 102, the first voltage divider unit and the ground terminal and includes resistors R13 and R14. Two terminals of the resistor R11 are electrically connected to the first signal terminal 101 and a first terminal of the resistor R12 respectively, a second terminal of the resistor R12 is electrically connected to the ground terminal and a first terminal of the resistor R13, and two terminals of the resistor R14 are electrically connected to the second signal terminal 102 and a second terminal of the resistor R13 respectively. The resistors R11 and R14 may have a large resistance value to limit the current. The first filter unit is electrically connected to the first voltage divider unit and the ground terminal and includes a capacitor C6 and a resistor R15. The second filter unit is electrically connected to the second voltage divider unit and the ground terminal and includes a capacitor C7 and a resistor R16. Two terminals of the capacitor C6 are electrically connected to the first terminal of the resistor R12 and a first terminal of the resistor R15 respectively, a second terminal of the resistor R15 is electrically connected to the ground terminal and a first terminal of the resistor R16, and two terminals of the capacitor C7 are electrically connected to the second terminal of the resistor R13 and a second terminal of the resistor R16 respectively. The first and second filter units may be used for high-pass filtering. The first clamping unit is electrically connected to the first filter unit and the ground terminal and includes a Zener diode D4. The second clamping unit is electrically connected to the second filter unit and the ground terminal and includes a Zener diode D5. A cathode of the Zener diode D4 is electrically connected to the first terminal of the resistor R15, an anode of the Zener diode D4 is electrically connected to the ground terminal and an anode of the Zener diode D5, and a cathode of the Zener diode D5 is electrically connected to the second terminal of resistor R16.

The amplitude adjustment module 20b includes a band-pass filter, a signal amplification circuit and a high-pass filter. The band-pass filter includes an operational amplifier Am4, resistors R17, R18, R19, R20, R21 and R22, and capacitors C8, C9, C10 and C11. A first terminal of the resistor R17 is electrically connected to sampling module 10b (the cathode of the Zener diode D4), and a second terminal of the resistor R17 is electrically connected to first terminals of the resistor R19, the capacitor C8 and the capacitor C10. A second terminal of the resistor R19 is electrically connected to the third signal terminal 103 which is a DC power source. A second terminal of the capacitor C10 is electrically connected to a first terminal of the resistor R21 and an inverting input terminal of the operational amplifier Am4, and second terminals of the capacitor C8 and the resistor R21 are both electrically connected to an output terminal of the operational amplifier Am4. A first terminal of the resistor R18 is electrically connected to the sampling module 10b (the cathode of the Zener diode D5), and a second terminal of the resistor R18 is electrically connected to first terminals of the resistor R20, the capacitor C9 and the capacitor C11. A second terminal of the resistor R20 is electrically connected to the third signal terminal 103, a second terminal of the capacitor C11 is electrically connected to a first terminal of the resistor R22 and a non-inverting input terminal of the operational amplifier Am4, and second terminals of the capacitor C9 and the resistor R22 are connected to each other. Based on the characteristic of the differential operational amplifier circuit that different amplitude regulations are made for different forms of signals (including common-mode and differential-mode signals), the second output signal is generated. The signal amplification circuit includes resistors R23 and R24 and an operational amplifier Am5. Two terminals of the resistor R23 are electrically connected to the output terminal of the operational amplifier Am4 and an inverting input terminal of the operational amplifier Am5 respectively. Two terminals of the resistor R24 are electrically connected to the inverting input terminal and an output terminal of the operational amplifier Am5 respectively, and a non-inverting input terminal of the operational amplifier Am5 is electrically connected to the third signal terminal 103. The high-pass filter includes a capacitor C12 and a resistor R25. Two terminals of the capacitor C12 are electrically connected to the output terminal of the operational amplifier Am5 and a first terminal of the resistor R25, and a second terminal of the resistor R25 is grounded. The high-pass filter may be used to suppress the DC component in the signal received from the third signal terminal 103.

The envelope extraction module 30b includes a diode D6, a resistor R26 and a capacitor C13. An anode of the diode D6 is electrically connected to the amplitude adjustment module 20b, and two terminals of the resistor R26 are electrically connected to a cathode of the diode D6 and the ground terminal. The capacitor C13 is electrically connected in parallel to the two terminals of the resistor R26.

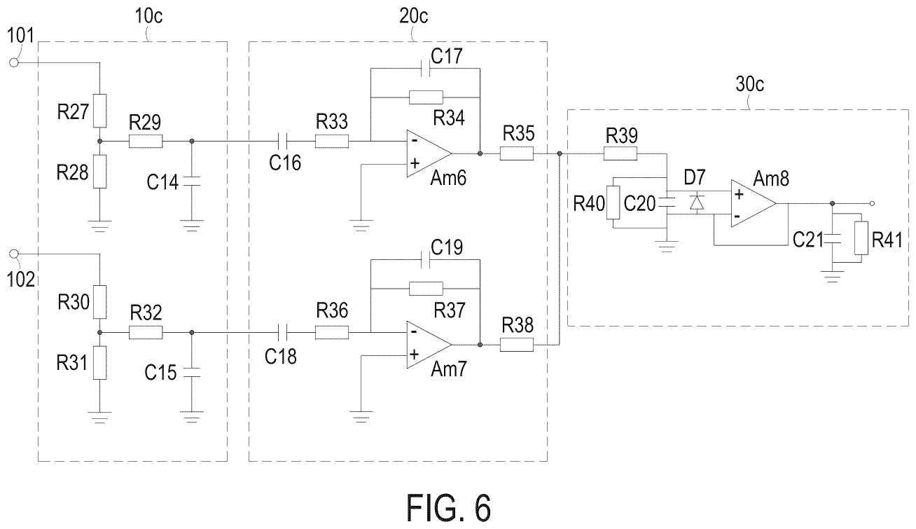

FIG. 6 exemplifies a specific circuit topology of the harmonic information extraction circuit according to further another embodiment of the present disclosure. In this embodiment, the first target band signal is included in the first sampling signal provided by the first signal terminal 101, and the second target band signal is included in the first sampling signal provided by the second signal terminal 102. As shown in FIG. 6, the sampling module 10c includes a first filter unit, a second filter unit, a first voltage divider unit and a second voltage divider unit. The first voltage divider unit is electrically connected to the first signal terminal 101 and the ground terminal and is configured to perform voltage dividing and current limiting on the first target band signal. The first voltage divider unit includes resistors R27 and R28 electrically connected in series between the first signal terminal 101 and the ground terminal. The first filter unit is electrically connected to the first voltage divider unit and the ground terminal and is a low-pass filter unit including a resistor R29 and a capacitor C14. A first terminal of the resistor R29 is electrically connected to a common node between the resistors R27 and R28, and two terminals of the capacitor C14 are electrically connected to a second terminal of the resistor R29 and the ground terminal respectively. The second voltage divider unit is electrically connected to the second signal terminal 102 and the ground terminal and is configured to perform voltage dividing and current limiting on the second target band signal. The second voltage divider unit includes resistors R30 and R31 electrically connected in series between the second signal terminal 102 and the ground terminal. The second filter unit is electrically connected to the second voltage divider unit and the ground terminal and is a low-pass filter unit including a resistor R32 and a capacitor C15. A first terminal of the resistor R32 is electrically connected to a common node between the resistors R30 and R31, and two terminals of the capacitor C15 are electrically connected to a second terminal of the resistor R32 and the ground terminal respectively.

The amplitude regulation module 20c includes a first high-pass filter and a second high-pass filter (both are active high-pass filters). The first high-pass filter includes an operational amplifier Am6, resistors R33, R34 and R35, and capacitors C16 and C17. Two terminals of the capacitor C16 are electrically connected to the first filter unit of the sampling module 10c and a first terminal of the resistor R33 respectively. An inverting input terminal of the operational amplifier Am6 is electrically connected to a second terminal of the resistor R33, a first terminal of the capacitor C17, and a first terminal of the resistor R34. A non-inverting input terminal of the operational amplifier Am6 is grounded, and an output terminal of the operational amplifier Am6 is electrically connected to a second terminal of the capacitor C17, a second terminal of the resistor R34 and a first terminal of the resistor R35. The second high-pass filter includes an operational amplifier Am7, resistors R36, R37 and R38, and capacitors C18 and C19. Two terminals of the capacitor C18 are electrically connected to the second filter unit of the sampling module 10c and a first terminal of the resistor R36 respectively. An inverting input terminal of the operational amplifier Am7 is electrically connected to a second terminal of the resistor R36, a first terminal of the capacitor C19 and a first terminal of the resistor R37. A non-inverting input terminal of the operational amplifier Am7 is grounded, and an output terminal of the operational amplifier Am7 is electrically connected to a second terminal of the capacitor C19, a second terminal of the resistor R37, and a first terminal of the resistor R38. Second terminals of the resistors R35 and R38 are electrically connected to each other.

The envelope extraction module 30c includes an operational amplifier Am8, resistors R39, R40 and R41, capacitors C20 and C21, and a diode D7. A first terminal of the resistor R39 is electrically connected to the amplitude regulation module 20c (the second terminals of the resistors R35 and R38), and a second terminal of the resistor R39 is electrically connected to a first terminal of the resistor R40, a first terminal of the capacitor C20, a cathode of the diode D7 and a non-inverting input terminal of the operational amplifier Am8. A second terminal of the resistor R40, a second terminal of the capacitor C20, an anode of the diode D7 and an inverting input terminal of the operational amplifier Am8 are grounded. Two terminals of the capacitor C21 are electrically connected to an output terminal of the operational amplifier Am8 and the ground terminal respectively. The resistor R41 is electrically connected in parallel to the capacitor C21.

It should be noted that in various embodiments and implementations exemplified in this disclosure, the resistors and capacitors of the envelope extraction module have a corresponding charging and discharging time constant (e.g., the cycle of charging and discharging) which is greater than the time constant corresponding to the highest frequency among all the target band signals (e.g., the cycle corresponding to the highest frequency, namely the reciprocal of the highest frequency). Thereby, the requirement for the sampling frequency of subsequent sampling circuits is reduced while extracting the harmonic information of the desired frequency band.

Further, it is noted that the specific topology of the electronic equipment which employs the harmonic information extraction circuit of the present disclosure is not limited.

In summary, the present disclosure provides a harmonic information extraction circuit capable of extracting harmonic signals of one or more target frequency bands from regular operating signals of an electronic equipment when multiple harmonic sources exist in the electronic equipment. Meanwhile, the signal of non-target frequency band is suppressed. Further, the health status of components of electronic equipment is obtained through extracting the harmonic information.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A harmonic information extraction circuit, comprising:
a sampling module, electrically connected to a first signal terminal and a second signal terminal of an electronic equipment, and configured to acquire a first sampling signal of the electronic equipment and generate a first output signal, wherein the first sampling signal comprises a first target band signal, a second target band signal and a non-target band signal;
an amplitude regulation module, electrically connected to the sampling module to receive the first output signal, configured to adjust at least one of an amplitude of the first target band signal and an amplitude of the second target band signal for ensuring that a ratio of the amplitude of the first target band signal to the amplitude of the second target band signal falls within a preset range, and generating a second output signal; and
an envelope extraction module, electrically connected to the amplitude regulation module to receive the second output signal, and extracting an envelope of the second output signal.

2. The harmonic information extraction circuit according to claim 1, wherein the sampling module comprises:
at least one filter unit, electrically connected to the first signal terminal, the second signal terminal, a ground terminal and the amplitude regulation module, and configured to suppress an amplitude of the non-target band signal.

3. The harmonic information extraction circuit according to claim 2, wherein the sampling module further comprises:
a voltage divider unit, electrically connected to the first signal terminal and the second signal terminal, and configured to perform voltage dividing and current limiting on the first sampling signal such that a maximum amplitude of the first output signal does not exceed a rated operating range of the amplitude regulation module.

4. The harmonic information extraction circuit according to claim 2, wherein the sampling module further comprises:
a clamping unit, electrically connected to the at least one filter unit, and configured to perform voltage clamping on the first sampling signal such that a maximum amplitude of the first output signal does not exceed a rated operating range of the amplitude regulation module.

5. The harmonic information extraction circuit according to claim 2, wherein the at least one filter unit makes attenuation of the amplitude of the first target band signal and the amplitude of the second target band signal not exceed a preset threshold.

6. The harmonic information extraction circuit according to claim 5, wherein the preset threshold is 0.3.

7. The harmonic information extraction circuit according to claim 1, wherein the sampling module comprises at least one filter unit, and when a frequency of the non-target band signal is lower than frequencies of the first target band signal and the second target band signal, the at least one filter unit comprises a high-pass filter or a band-pass filter which allows the first target band signal and the second target band signal to pass through.

8. The harmonic information extraction circuit according to claim 1, wherein the sampling module comprises at least one filter unit, and when a frequency of the non-target band signal is higher than frequencies of the first target band signal and the second target band signal, the at least one filter unit comprises a low-pass filter or a band-pass filter which allows the first target band signal and the second target band signal to pass through.

9. The harmonic information extraction circuit according to claim 1, wherein the first target band signal is a differential-mode signal, the second target band signal is a common-mode signal, and the sampling module comprises:
a first voltage divider unit, electrically connected to the first signal terminal and the ground terminal;
a first filter unit, electrically connected to the first voltage divider unit and the ground terminal;
a first clamping unit, electrically connected to the first filter unit and the ground terminal;
a second voltage divider unit, electrically connected to the second signal terminal, the first voltage divider unit and the ground terminal;
a second filter unit, electrically connected to the second voltage divider unit and the ground terminal; and
a second clamping unit, electrically connected to the second filter unit and the ground terminal.

10. The harmonic information extraction circuit according to claim 1, wherein the sampling module comprises:
a first voltage divider unit, electrically connected to the first signal terminal and the ground terminal, and configured to perform voltage dividing and current limiting on the first target band signal;
a first filter unit, electrically connected to the first voltage divider unit and the ground terminal;
a second voltage divider unit, electrically connected to the second signal terminal and the ground terminal, and configured to perform voltage dividing and current limiting on the second target band signal; and
a second filter unit, electrically connected to the second voltage divider unit and the ground terminal.

11. The harmonic information extraction circuit according to claim 1, wherein the amplitude regulation module comprises:
at least one band-pass filter, electrically connected between the sampling module and the envelope extraction module, configured to adjust at least one of the amplitude of the first target band signal and the amplitude of the second target band signal, wherein the at least one band-pass filter comprises an active band-pass filter or a passive band-pass filter.

12. The harmonic information extraction circuit according to claim 11, wherein the amplitude regulation module further receives a second sampling signal comprising a third target band signal, and a ratio of an amplitude of the third target band signal to the amplitude of the first target band signal falls within the preset range.

13. The harmonic information extraction circuit according to claim 12, wherein the amplitude regulation module further comprises:
a signal amplification circuit, electrically connected between the at least one band-pass filter and the envelope extraction module, and configured to provide the second sampling signal.

14. The harmonic information extraction circuit according to claim 12, wherein the amplitude regulation module further comprises:
a high-pass filter, electrically connected to the at least one band-pass filter and the envelope extraction module, and configured to suppress a DC component of the second sampling signal.

15. The harmonic information extraction circuit according to claim 12, wherein the at least one band-pass filter is further configured to suppress at least one of a DC component and high-frequency noise of the second sampling signal.

16. The harmonic information extraction circuit according to claim 12, wherein a charging and discharging time constant of the envelope extraction module is greater than a time constant corresponding to a highest frequency among the first target band signal, the second target band signal and the third target band signal.

17. The harmonic information extraction circuit according to claim 1, wherein the preset range is [0.01, 100].

18. The harmonic information extraction circuit according to claim 17, wherein the preset range comprises:
a first preset range which is [0.2, 5];
a second preset range which is [0.01, 0.2); and
a third preset range which is (5, 100],
wherein when the preset range is the first preset range, the envelope of the second output signal reflects information of both the first target band signal and the second target band signal; when the preset range is the second preset range, the envelope of the second output signal reflects information of the second target band signal; and when the preset range is the third preset range, the envelope of the second output signal reflects information of the first target band signal.

19. The harmonic information extraction circuit according to claim 1, wherein the envelope extraction module comprises:
a diode, having an anode electrically connected to the amplitude regulation module;
a resistor, electrically connected between a cathode of the diode and the ground terminal; and
a capacitor, electrically connected in parallel to two terminals of the resistor.

20. The harmonic information extraction circuit according to claim 19, wherein the envelope extraction module further comprises:
a voltage follower, wherein a non-inverting input terminal of the voltage follower is electrically connected to the amplitude regulation module, and an output terminal of the voltage follower is electrically connected to the anode of the diode.

21. The harmonic information extraction circuit according to claim 1, wherein a charging and discharging time constant of the envelope extraction module is greater than a time constant corresponding to a highest frequency among the first target band signal and the second target band signal.
